(19) United States
(12) Patent Application Publication
(10) Pub. No.: US 2025/0143026 A1
(43) Pub. Date: May 1, 2025

(54) SEMICONDUCTOR LIGHT-EMITTING DEVICE

(71) Applicant: EPISTAR CORPORATION, Hsinchu (TW)

(72) Inventors: Hsin-Ying WANG, Hsinchu (TW); Chao-Hsing CHEN, Hsinchu (TW); Chi-Ling LEE, Hsinchu (TW); Chen OU, Hsinchu (TW); Min-Hsun HSIEH, Hsinchu (TW)

(21) Appl. No.: 19/009,855

(22) Filed: Jan. 3, 2025

Related U.S. Application Data
(62) Division of application No. 17/202,001, filed on Mar. 15, 2021.

(30) Foreign Application Priority Data
Mar. 17, 2020 (TW) 109108789

(51) Int. Cl. H10H 20/831; H01L 25/13; H10H 20/833

(52) U.S. Cl. CPC H10H 20/831; H01L 25/13; H10H 20/833

(57) ABSTRACT

A semiconductor light-emitting device includes: a semiconductor stack, including; an active layer, formed on the semiconductor stack; a second semiconductor contact layer formed on the active layer; and a recessed region formed in the semiconductor stack and including a part of the upper surface; a transparent electrode on the second semiconductor contact layer; a protective layer on semiconductor stack, including a first and second opening; a first electrode pad in the first opening and connected with the first semiconductor contact layer; and a second electrode pad in the second opening and connected to the transparent electrode. The semiconductor light-emitting device receives an operating current having ratio to the area of the transparent electrode that ranges from 10 mA/mm² to 1000 mA/mm². In a top view, the active layer surrounds the recessed region. The semiconductor stack and the transparent electrode layer each includes an edge adjacent to the recessed region.

### CROSS-REFERENCE TO RELATED APPLICATIONS

This application is a divisional application of U.S. patent application Ser. No. 17/202,001, filed on Mar. 15, 2021, which claims the benefit of Taiwan patent application No. 109108789 filed on Mar. 17, 2020, and the entire content of which are hereby incorporated by reference herein in their entirety.

### BACKGROUND

### Technical Field

The present application relates to a semiconductor light-emitting device, more specifically, to a semiconductor light-emitting device having a transparent electrode.

### Description of the Related Art

Semiconductor light-emitting devices have the advantages of low power consumption, high brightness, high color rendering, and small size. The semiconductor light-emitting devices have been widely used in lighting and display. For example, the semiconductor light-emitting devices can substitute the display pixels of a traditional liquid crystal display thereby achieving better display quality. In addition, the semiconductor light-emitting devices can be used as the backlight source of the display and the brightness of the semiconductor light-emitting devices in different zones can be independently adjusted, thereby achieving greater contrast ratio.

### SUMMARY

A semiconductor light-emitting device includes: a semiconductor stack, including: a first semiconductor contact layer with an upper surface; an active layer, formed on the upper surface of the first semiconductor contact layer; a second semiconductor contact layer, formed on the active layer; and a recessed region, formed in the semiconductor stack and including a part of the upper surface of the first semiconductor contact layer; a transparent electrode on the second semiconductor contact layer; a protective layer on semiconductor stack, including a first opening and a second opening; a first electrode pad, filling in the first opening and electrically connect with the first semiconductor contact layer; and a second electrode pad, filling in the second opening and electrically connect the transparent electrode; wherein: the semiconductor light-emitting device receives an operating current while being operated, and a ratio of the operating current to the area of the transparent electrode ranges from 10 mA/mm² to 1000 mA/mm²; and wherein in a top view, the active layer surrounds the recessed region; the semiconductor stack includes a contour with a first edge and a second edge opposite to the first edge, a third edge and a fourth edge are opposite to the third edge, and the fourth edge is adjacent to the recessed region; the transparent electrode layer includes s a fifth edge and a sixth edge opposite to the fifth edge, a seventh edge and an eighth edge opposite the seventh edge, and the eighth edge is adjacent to the recessed region; the fifth edge is closer to the first edge than the sixth edge; and a minimum distance between the fifth edge and the first edge is smaller than the eighth edge and the fourth edge.

### BRIEF DESCRIPTION OF THE DRAWINGS

FIG. 1A shows a top view of a semiconductor light-emitting device in accordance with a first embodiment of the present application.

FIG. 1B shows a cross-sectional view of the semiconductor light-emitting device in accordance with the first embodiment of the present application.

FIG. 2A shows a top view of a semiconductor light-emitting device in accordance with a second embodiment of the present application.

FIG. 2B shows a cross-sectional view of the semiconductor light-emitting device in accordance with the second embodiment of the present application.

FIG. 3A shows a top view of a semiconductor light-emitting device in accordance with a third embodiment of the present application.

FIG. 3B shows a cross-sectional view of the semiconductor light-emitting device in accordance with the third embodiment of the present application.

FIG. 4A shows a top view of a semiconductor light-emitting device in accordance with a fourth embodiment of the present application.

FIG. 4B shows a cross-sectional view of the semiconductor light-emitting device in accordance with the fourth embodiment of the present application.

FIG. 5 shows a light-emitting assembly having a carrier and a semiconductor light-emitting device in accordance with an embodiment of the present application bonded on the carrier.

FIG. 6 shows another light-emitting assembly having a carrier and a plurality of semiconductor light-emitting devices in accordance with an embodiment of the present application bonded on the carrier.

### DETAILED DESCRIPTION OF THE EMBODIMENTS

To better and concisely explain the disclosure, the same name or the same reference number given or appeared in different paragraphs or figures along the specification should has the same or equivalent meanings while it is once defined anywhere of the disclosure.

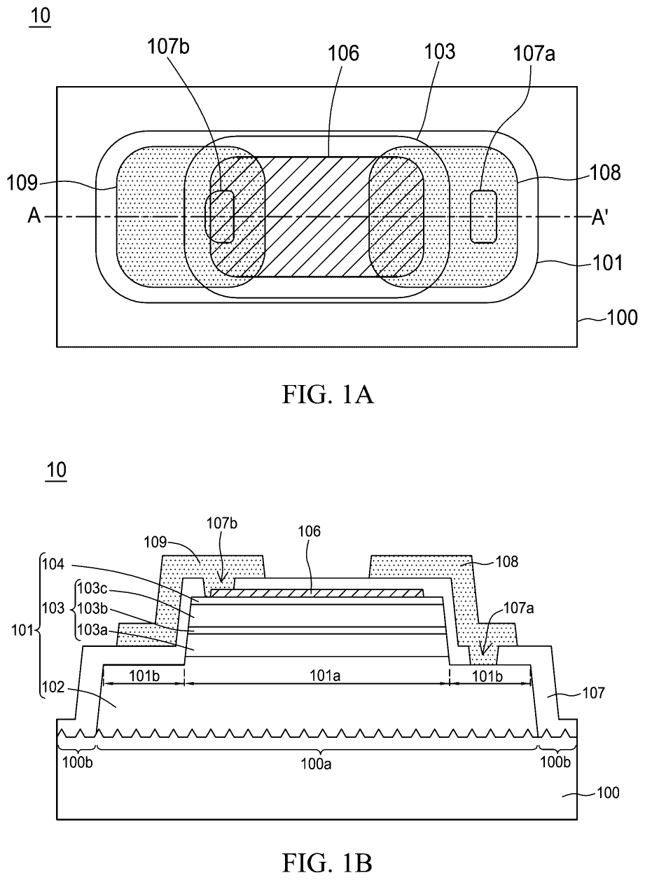

FIG. 1A shows a semiconductor light emitting device 10 in accordance with a first embodiment of the present application. FIG. 1B is a cross-sectional view taken along the A-A′ line shown in FIG. 1A. The semiconductor light-emitting device 10 includes a substrate 100, a semiconductor stack 101 including a first semiconductor contact layer 102, a light-emitting stack 103, and a second semiconductor contact layer 104 sequentially formed on the substrate 100, a transparent electrode 106 formed on and electrically connected to the second semiconductor contact layer 104, a protective layer 107 covering the above-mentioned structures and including a first opening 107a and a second opening 107b respectively exposing the first semiconductor contact layer 102 and a part of the upper surface of the transparent electrode 106, a first electrode pad 108 filled in the first opening 107a to be electrically connect the first semiconductor contact layer 102, and a second electrode pad 109 filled in the second opening 107b to electrically connect the transparent electrode 106. The first opening 107a is located directly below the first electrode pad 108 and the second opening 107b is located directly below the second electrode pad 109. Specifically, the second opening 107b exposes a part of the transparent electrode 106 and a part of the second semiconductor contact layer 104, and the second electrode pad 109 fills the second opening 107b to contact the transparent electrode 106 and the second semiconductor contact layer 104. The interface between the second electrode pad 109 and the transparent electrode 106 is a low-resistance interface such an ohmic contact interface. The interface between the second electrode pad 109 and the second semiconductor contact layer 104 is a high-resistance interface such a Schottky contact interface. Therefore, most of the operating current injected into the second electrode pad 109 flows into the transparent electrode 106 and then into the light-emitting stack 103.

In another embodiment, the second opening 107b is completely located on the transparent electrode 106, and the second opening 107b exposes the upper surface of the transparent electrode 106 but does not expose the upper surface of the second semiconductor contact layer 104. The upper surface of the substrate 100 includes an operating region 100a and a non-operating region 100b. The semiconductor stack 101 is formed on the operating region 100a. The non-operating region 100b is not covered by the semiconductor stack 101 and exposes a partial surface of the substrate 100. As shown in FIGS. 1A and 1B, the non-operating region 100b surrounds the operating region 100a. The width of the substrate 100 is greater than the width of the semiconductor stack 101. In one embodiment, the protective layer 107 extends to cover the non-operating region 100b and contact the substrate 100. The semiconductor stack 101 includes an active region 101a and a recessed region 101b. The light emitting stack 103 is formed in the active region 101a. The light-emitting stack 103 is not formed on the recessed region 101b and the recessed region 101b exposes a part of the upper surface of the first semiconductor contact layer 102. As shown in FIG. 1A, the recessed region 101b surrounds the active region 101a or an active layer 103b. As shown in FIG. 1B, the width of the first semiconductor contact layer 102 is greater than the width of the light-emitting stack 103. In one embodiment, as shown in FIG. 1A, each of the first electrode pad 108 and the second electrode pad 109 includes a portion overlapping the recessed region 101b and another portion overlapping the active region 101a or the active layer 103b. The first opening 107a is located on the recessed region 101b and the second opening 107b is located on the transparent electrode 106. As shown in FIG. 1A, the ratio of the overlapping portions of the second electrode pad 109 and the recessed region 101b to the area of the second electrode pad 109 is greater than or equal to 0.2 and less than 1, preferably, greater than or equal to 0.5 and less than 1. The ratio of the area of the first electrode pad 108 or the second electrode pad 109 to the area of the transparent electrode 106 is 0.5 to 5. In one embodiment, the area of the first electrode pad 108 or the second electrode pad 109 is larger than the area of the transparent electrode 106. As shown in FIG. 1A, the ratio of the area of the substrate 100 to the area of the operating region 101a or the active layer 103b is 2 to 50. As shown in FIG. 1B, the second electrode pad 109 covers a part of the transparent electrode 106.

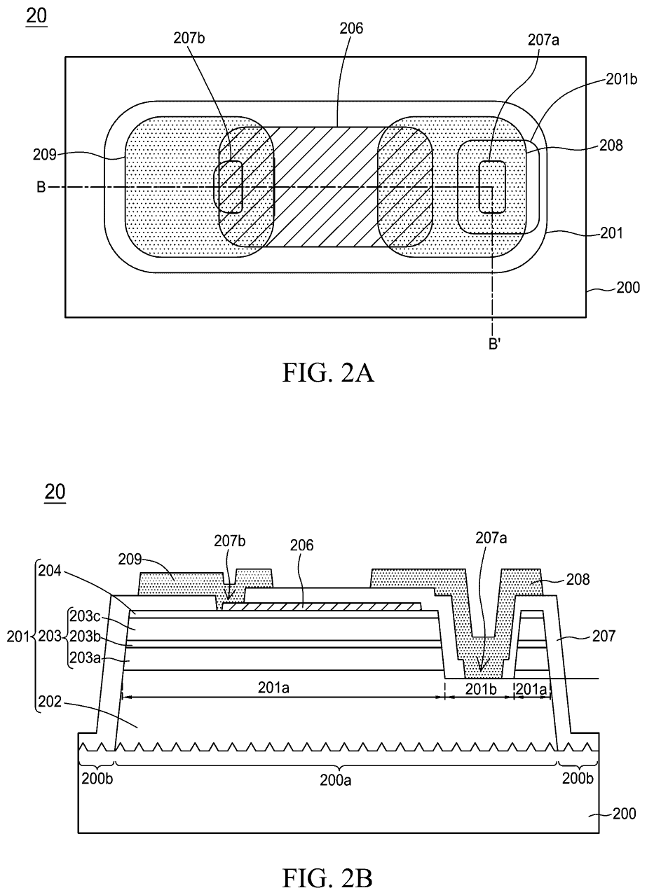

FIG. 2A shows a top view of a semiconductor light-emitting device 20 in accordance with a second embodiment of the present application. FIG. 2B shows a cross-sectional view taken along the B-B′ line in FIG. 2A. The semiconductor light-emitting device 20 includes a substrate 200, a semiconductor stack 201 including a first semiconductor contact layer 202, a light-emitting stack 203 and a second semiconductor contact layer 204 sequentially formed on the substrate 200, a transparent electrode 206 formed on and electrically connected to the second semiconductor contact layer 204, a protective layer 207 covering the above-mentioned structures and including a first opening 207a and a second opening 207b respectively exposing the first semiconductor contact layer 202 and a part of the upper surface of the transparent electrode 206, a first electrode pad 208 filled in the first opening 207a and electrically connected to the first semiconductor contact layer 202, and a second electrode pad 209 filled in the second opening 207b to electrically connect the transparent electrode 206. The first opening 207a is located directly below the first electrode pad 208 and the second opening 207b is located directly below the second electrode pad 209. The upper surface of the substrate 200 includes an operating region 200a and a non-operating region 200b. The semiconductor stack 201 is formed on the operating region 200a, and the non-operating region 200b is not covered by the semiconductor stack 201. As shown in FIGS. 2A and 2B, the non-operating region 200b surrounds the operating region 200. The width of the substrate 200 is greater than the width of the semiconductor stack 201. In one embodiment, the protective layer 207 extends to cover the non-operating region 200b and contacts the substrate 200. The semiconductor stack 201 includes an active region 201a and a recessed region 201b. The light-emitting stack 203 is formed on the active region 201a. The light-emitting stack 203 is not formed on the recessed region 201b and the recessed region 201b exposes the surface of the first semiconductor contact layer 202. The first opening 207a is located on the recessed region 201b and the second opening 207b is located on the transparent electrode 206. Specifically, the second opening 207b exposes a part of the transparent electrode 206 and a part of the second semiconductor contact layer 104, and the second electrode pad 209 fills the second opening 207b to contact the transparent electrode 206 and the second semiconductor contact layer 204. The interface between the second electrode pad 209 and the transparent electrode 206 is a low-resistance interface such an ohmic contact interface. The interface between the second electrode pad 209 and the second semiconductor contact layer 204 is a high-resistance interface such a Schottky contact interface. Therefore, most of the operating current injected into the second electrode pad 209 flows into the transparent electrode 206 and then into the light-emitting stack 203. In another embodiment, the whole second opening 207b is located on the transparent electrode 206, and the second opening 207b exposes the upper surface of the transparent electrode 206 but does not expose the surface of the second semiconductor contact layer 104.

One difference between the second embodiment and the first embodiment is that the recessed region 201a is formed only on one side of the semiconductor stack 201. As shown in FIG. 2A, the recessed region 201b is surrounded by the active region 201a or the active layer 203b. A part of the first electrode pad 208 overlaps the recessed region 201b and another part of the first electrode pad 208 overlaps the active area 201a or the active layer 203b. The whole second electrode pad 209 is located on the active area 201a. As shown in FIG. 2B, the first electrode pad 208 crosses the two sides of the recessed region 201b and extends to the upper surface of the light-emitting stack 203 so that a substantial portion of the first electrode pad 208 is located on the light-emitting stack 203. The second electrode pad 209 covers the transparent electrode 206 and extends to the upper surface of the light-emitting stack 203 so that the whole second electrode pad 209 is located on the light-emitting stack 203. In this way, in a process of bonding the semiconductor light-emitting element 20 to a carrier (not shown), the yield loss due to that the height difference between the first electrode pad 208 and the second electrode pad 209 can be prevented. As shown in FIG. 2A, the ratio of the area of the first electrode pad 208 or the second electrode pad 209 to the area of the transparent electrode 206 is 0.5 to 5. In one embodiment, the area of the first electrode pad 208 or the second electrode pad 209 is larger than the area of the transparent electrode 206. As shown in FIG. 2A, the ratio of the area of the substrate 200 to the area of the operating region 201a or the active layer 203b is 2 to 50.

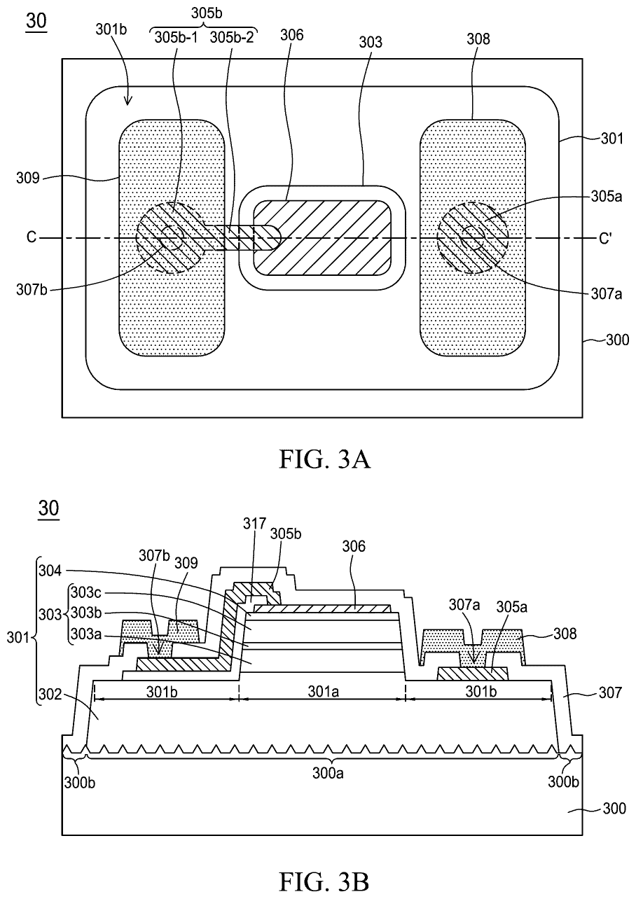

FIG. 3A shows a top view showing a semiconductor light-emitting device 30 in accordance with a third embodiment of the present application. FIG. 3B shows a cross-sectional view taken along the C-C′ line in FIG. 3A. The semiconductor light-emitting device 30 includes a substrate 300, a semiconductor stack 301 including a first semiconductor contact layer 302, a light-emitting stack 303 and a second semiconductor contact layer 304 sequentially formed on the substrate 300, a transparent electrode 306 formed on and electrically connected to the second semiconductor contact layer 304, an insulating layer 317 formed on the semiconductor stack 301 and exposing a part of the upper surface of the transparent electrode 306, a first connecting electrode 305a formed on and electrically connected to the first semiconductor contact layer 302, a second connecting electrode 305b formed on the insulating layer 317 and the transparent electrode 306 and electrically connected to the transparent electrode 306, a protective layer 307 formed on the first connecting electrode 305a and the second connecting electrode 305b and including a first opening 307a and a second opening 307b respectively exposing a part of the upper surface of the first connecting electrode 305a and the second connecting electrode 305b, a first electrode pad 308 filled in the first opening 307a to electrically connect the first connecting electrode 305a, and a second electrode pad 309 filled in the second opening 307b to electrically connect the second connecting electrode 305b. The first opening 307a is directly located below the first electrode pad 308 and the second opening 307b is directly located below the second electrode pad 309. The upper surface of the substrate 300 includes an operating region 300a and a non-operating region 300b. The semiconductor stack 301 is formed on the operating region 300a. The non-operating region 300b is not covered by the semiconductor stack 301. As shown in FIGS. 3A and 3B, the non-operating region 300b surrounds the operating region 300a. The width of the substrate 300 is greater than the width of the semiconductor stack 301. In one embodiment, the protective layer 307 extends to cover the non-operating region 300b and contacts the substrate 300. The semiconductor stack 301 includes an active region 301a and a recessed region 301b. The light emitting stack 303 is formed in the operating region 301a. The light-emitting stack 303 is not formed on the recessed region 301b and the recessed region 301b exposes a part of the upper surface of the first semiconductor contact layer 302. As shown in FIG. 3A, the recessed region 301b surrounds the active area 302a or the active layer 303b. One difference between the third embodiment and the first embodiment is that the whole first electrode pad 308 and the whole second electrode pad 309 are located outside the operating region 301a or the active layer 303b. As shown in FIG. 3A, the whole first electrode pad 308 and the whole second electrode pad 309 are located on the recessed region 301b, that is, the ratio of the overlapping area of the second electrode pad 309 and the recessed area 301b to the area of the second electrode pad 309 is 1. The first electrode pad 308 is electrically connected to the first semiconductor contact layer 302 through the first connecting electrode 305a and the second electrode pad 309 is electrically connected to the transparent electrode 306 through the second connecting electrode 305b. The first opening 307a and the second opening 307b are both located on the recessed region 301b and directly below the first electrode pad 308 and the second electrode pad 309, respectively. The first connecting electrode 305a is directly located below the first opening 307a so that the first electrode pad 308 fills the first opening 307b and is electrically connected to the first connecting electrode 305a. As shown in FIG. 3B, the width of the first connecting electrode 305a is larger than the width of the first opening 307b and smaller than the width of the first electrode pad 308. In another embodiment, the first connecting electrode 305a can be omitted if the first electrode pad 308 ohmic contacts the first semiconductor contact layer 302. As shown in FIG. 3A, the second connecting electrode 305b includes a bonding portion 305b-1 and an extension portion 305b-2. The extension portion 305b-2 extends from the bonding portion 305b-1 beyond the covering of the second electrode pad 309 and to the transparent electrode 306 for conducting current to the transparent electrode 306. In the direction perpendicular to the extending direction of the extension portion 305b-2, the extending portion 305b-2 has a width smaller than that of the bonding portion 305b-1. The insulating layer 317 is interposed between the second connecting electrode 305b and the light-emitting stack 303 to prevent the second connecting electrode 305b and the light-emitting stack 303 from being short-circuited. In one embodiment, as shown in FIG. 3A, the area of the first electrode pad 308 or the second electrode pad 309 is larger than the area of the transparent electrode 306. The ratio of the area of the substrate 300 to the area of the operating region 301a or the active layer 303b ranges from 4 to 100, preferably from 10 to 100. The first connecting electrode 305a and the second connecting electrode 305b include a single metal layer or a multi-layered metal structure for forming good electrical contact such as ohmic contact with the first semiconductor contact layer 302 and the transparent electrode 306, respectively.

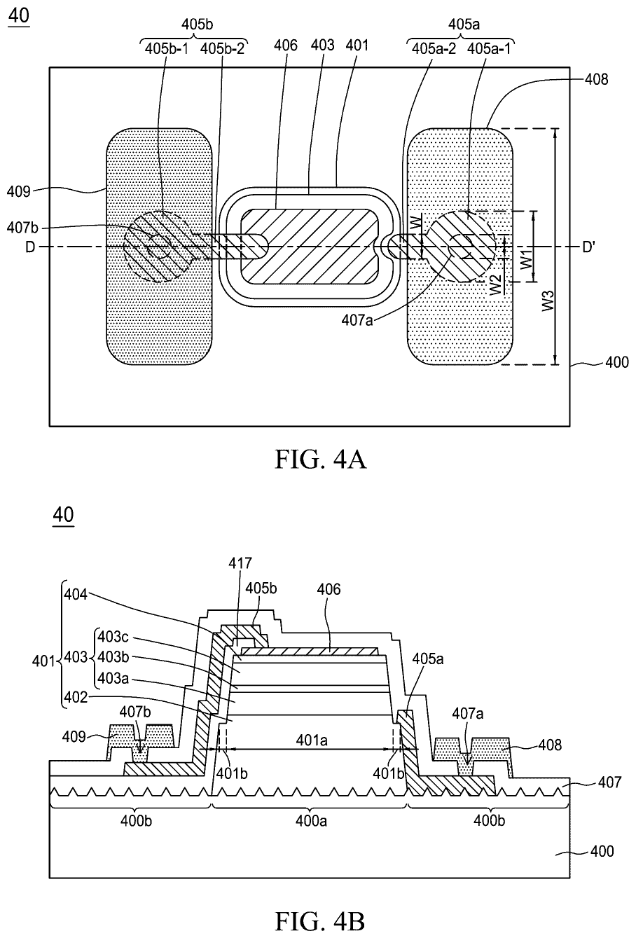

FIG. 4A shows a top view of a semiconductor light-emitting device 40 in accordance with a fourth embodiment of the present application. FIG. 4B shows a cross-sectional view taken along the D-D′ line in FIG. 4A. The semiconductor light-emitting device 40 includes a substrate 400, a semiconductor stack 401 including a first semiconductor contact layer 402, a light-emitting stack 403 and a second semiconductor contact layer 404 sequentially formed on the substrate 400, a transparent electrode 406 formed on and electrically connected to the second semiconductor contact layer 404, an insulating layer 417 formed on the substrate 400 and the semiconductor stack 401 and exposing a part of the upper surface of the transparent electrode 406, a first connecting electrode 405a formed on the substrate 400 and extending to and electrically connecting to the first semiconductor contact layer 402, a second connecting electrode 405b formed on the insulating layer 417 and the transparent electrode 406 and electrically connected to the transparent electrode 406, a protective layer 407 formed on the first connecting electrode 405a and the second connecting electrode 405b and including a first opening 407a and a second opening 407b respectively exposing a part of the upper surface of the first connecting electrode 405a and the second connecting electrode 405b, a first electrode pad 408 filled in the first opening 407a to electrically connect the first connecting electrode 405a, and a second electrode pad 409 filled in the second opening 407b to electrically connect to the second connecting electrode 405b. The first opening 407a is located below the first electrode pad 408 and the second opening 407b is located below the second electrode pad 409. The upper surface of the substrate 400 includes an operating region 400a and a non-operating region 400b. The semiconductor stack 401 is formed on the operating region 400a. The non-operating region 400b is not covered by the semiconductor stack 401. As shown in FIGS. 4A and 4B, the non-operating region 400b surrounds the operating region 400a. The width of the substrate 400 is greater than the width of the semiconductor stack 401. In one embodiment, the protective layer 407 extends to cover the non-operating region 400b and contacts the substrate 400. The semiconductor stack 401 includes an active region 401a and a recessed region 401b. The light emitting stack 403 is formed on the active region 401a. The light-emitting stack 403 is not formed on the recessed region 401b and the recessed region 401b exposes a part of the upper surface of the first semiconductor contact layer 402. As shown in FIG. 4A, the recessed region 401b surrounds the active area 402a or the active layer 403b.

One difference between the fourth embodiment and the third embodiment is that the whole first electrode pad 408 and the whole second electrode pad 409 are located outside the active region 401a (or the active layer 403b) and the semiconductor stack 401. As shown in FIG. 4A, the whole first electrode pad 408 and the whole second electrode pad 409 are located in the non-operating region 400b. The first electrode pad 408 is electrically connected to the first semiconductor contact layer 402 through the first connecting electrode 405a, and the second electrode pad 409 is electrically connected to the transparent electrode 406 through the second connecting electrode 405b. The first opening 407a and the second opening 407b are both located on the non-operating region 400b and below the first electrode pad 408 and the second electrode pad 409, respectively. The first connecting electrode 405a is located below the first opening 407a so that the first electrode pad 408 electrically connects the first connecting electrode 405a via the first opening 407a. As shown in FIG. 4A, the first connecting electrode 405a includes a bonding portion 405a-1 and an extension portion 405a-2. The extension portion 405a-2 extends from the bonding portion 405a-1 beyond the covering of the first electrode pad 408 to connect the first semiconductor contact layer 402. The extension portion 405a-2 can conduct current to the first semiconductor contact layer 402. In the direction perpendicular to the extending direction of the extension portion 405a-2, the extending portion 405a-2 has a width W smaller than a width W1 of the bonding portion 405a-1. The second connecting electrode 405b includes a bonding portion 405b-1 and an extension portion 405b-2. The extension portion 405b-2 extends from the bonding portion 405b-1 beyond the covering of the second electrode pad 409 and to the transparent electrode 406. The extension portion 405b-2 can conduct current to the transparent electrode 406. Being the same as the extending portion 405a-2, in the direction perpendicular to the extending direction of the extension portion 405b-2, the extending portion 405b-2 has a width smaller than that of the bonding portion 405b-1. As shown in FIG. 4A, the width W1 of the bonding portions 405a-1 and the 405b-1 are respectively larger than the width W2 of the first opening 407a and the second opening 407b, and smaller than the width W3 of the first electrode pad 408 and the second electrode pad 409 in the top view.

The insulating layer 417 is interposed between the second connecting electrode 405b and the light-emitting stack 403 to prevent the second connecting electrode 405b and the light-emitting stack 403 from being short-circuited. In one embodiment, as shown in FIG. 4A, the area of the first electrode pad 408 or the second electrode pad 409 is larger than the area of the transparent electrode 406. The ratio of the area of the substrate 400 to the area of the semiconductor stack 401 ranges from 4 to100, preferably from 10 to 100. In one embodiment, in a top view, the ratio of the area of the top surface of the active region 401a or the top surface of the active layer 403b to the area the top surface of the semiconductor stack 401 ranges from 0.7 to 0.95. In embodiment, the first connecting electrode 405a and the second connecting electrode 405b include a single metal layer or a multi-layered metal structure to form good electrical contact such as ohmic contact with the first semiconductor contact layer 302 and the transparent electrode 306.

In the above-mentioned embodiments, the elements with the same name represent the corresponding elements in each embodiment, and have the same characteristics such as the same materials and functions. The detailed descriptions of the elements are as follows.

In the above-mentioned embodiments, the transparent electrodes 106, 206, 306 and 406 and the second semiconductor contact layers 104, 204, 304 and 404 form a low-resistance interface, such as an ohmic contact interface. The current injecting into the second electrode pads 109, 209, 309 and 409 mainly flows into the light-emitting stack 103, 203, 303 and 403 through the transparent electrodes 106, 206, 306 and 406 so that the main light-emitting area is confined in the area under the transparent electrode. Therefore, the current density within the light-emitting stacks 103, 203, 303 and 403 is approximately the same as the current density within the transparent electrodes 106, 206, 306 and 406. By adjusting the area of the transparent electrode, the current density in the transparent electrode can be adjusted.

In one embodiment, when the semiconductor light-emitting device 10 (20, 30 or 40) is applied to a display light source, the operating current received by the semiconductor light-emitting device 10 (20, 30 or 40) is, for example, 0.01 mA to 2 mA. In order to ensure that the current density in the light-emitting stack 103 (203, 303 and 403) is within an appropriate range to keep external quantum efficiency (EQE) stable and to prevent the current density from being too small which causes the great drop of EQE, the size of semiconductor light-emitting device 10 (20, 30 or 40) can be reduced accordingly to achieve the appropriate current density. However, if the size of the semiconductor light-emitting device is reduced, the subsequent manufacturing process such as die-sorting, testing or die-bonding may become difficult. Therefore, the semiconductor light-emitting device 10 (20, 30 or 40) and the electrode pads thereof are preferably not smaller than a specific size. In the embodiments of the present application, the current density in the transparent electrode can be adjusted by designing the area of the transparent electrode, thereby substantially controlling the current density in the light-emitting stack and keep the semiconductor light-emitting device not smaller than the specific size.

In one embodiment, the semiconductor light-emitting device 10 (20, 30 or 40) is a light-emitting diode chip (LED chip), for example, a mini-LED or micro-LED chip. As shown in FIG. 1A, the substrate 100 (200, 300 or 400) has a length X and a width Y (Y<X). In one embodiment, the length X is not less than 10 μm. In one embodiment, the length X ranges from 10 μm to 300 μm, preferably 20 μm to 100 μm. In one embodiment, the ratio (Y/X) of the width Y to the length X is 0.2 to 0.8. The transparent electrode has a length and a width smaller than the length, wherein the length is between 5 μm and 50 μm. In one embodiment, the ratio (R2) of the operating current injected into the semiconductor light-emitting device 10 (20, 30 or 40) to the area of the transparent electrode 106 (206, 306 or 406) is not less than 10 mA/mm². In one embodiment, the ratio (R2) ranges from 10 mA/mm² to 1000 mA/mm², preferably from 250 mA/mm² to 1000 mA/mm². The ratio (R1) of the area of the substrate 100 (200, 300 or 400) to the area of the transparent electrode 106 (206, 306 or 406) ranges from 2 to 100, preferably from 3 to 50.

In the above-mentioned embodiments, the light-emitting stack 103 (203, 303 and 403) includes a first semiconductor confinement layer 103a (203a, 303a and 403a) on the first semiconductor contact layer 102 (202, 302 and 402), and the active layer 103b (203b, 303b and 403b) on the first semiconductor cladding layer 103a (203a, 303a and 403a), and a second semiconductor confinement layer 103c (203c, 303c and 403c) is located on the active layer 103b (203b, 303b and 403b). The first semiconductor confinement layer 103a (203a, 303a and 403a) has a first conductivity type and the second semiconductor confinement layer 103c (203c, 303c and 403c) has a second conductivity type different from the first conductivity type. The second conductivity type is, for example, p-type to provide holes to the active layer 103b (203b, 303b and 403b), and the first conductivity type is, for example, n-type to provide electrons to the active layer 103b (203b, 303b and 403b). The electrons and holes are combined in the active layer 103b (203b, 303b and 403b) to emit light with a specific wavelength.

In the above-mentioned embodiments, the substrate 100 (200, 300, and 400) is an epitaxy substrate for epitaxy growth of the first semiconductor contact layers 102 (202, 302 and 402) and the light-emitting stack 103 (203, 303 and 403) by, for example, metal organic chemical vapor deposition (MOCVD). In one embodiment, the light emitted from the semiconductor light-emitting device 10 (20, 30 and 40) is mainly escaped from the rear side of the substrate 100 (200, 300, and 400) and the material of the substrate is transparent to the light emitted by the active layer 103b (203b, 303b and 403b). In another embodiment, the light emitted from the semiconductor light-emitting device 10 (20, 30 and 40) is mainly escaped from the protective layer 107 (207, 307 and 407) and the material of the substrate can be transparent or opaque to the light emitted by the active layer. From the top view, the shape of the substrate 100 (200, 300, and 400) is, for example, a rectangle. In one embodiment, the upper surface of the substrates 100 (200, 300, and 400) includes a plurality of protrusions separated from each other, which is able to change the path of the light to increase the light extraction efficiency. In one embodiment, the plurality of protrusions is formed by patterning the surface of the substrate 100 (200, 300, and 400) to a depth, and therefore the plurality of protrusions has the same material as the substrate 100 (200, 300, and 400). In another embodiment, the plurality of protrusions and the substrate 100 (200, 300, and 400) have different materials. That is, a light-transmitting material different form the material of the substrate is formed on the upper surface of the substrate 100 (200, 300, and 400), and then the light-transmitting material is patterned to form the plurality of protrusions.

The first semiconductor contact layers 102, 202, 302 and 402, the first semiconductor confinement layers 103a, 203a, 303a and 403a, the active layers 103b, 203b, 303b and 403b, the second semiconductor confinement layers 103c, 203c, 303c and 403c, and the second semiconductor contact layers 104, 204, 304 and 404 include III-V group compound semiconductor materials, such as AlInGaAs-based semiconductor, AlGaInP-based semiconductor or AlInGaN-based semiconductor. The AlInGaAs-based semiconductor can be expressed as AlₓIn_{y}Ga_{(1-x-y)}As, the AlInGaP-based semiconductor can be expressed as AlₓIn_{y}Ga_{(1-x-y)}P, and the AlInGaN-based semiconductor can be expressed as AlₓIn_{y}Ga_{(1-x-y)}N, where 0≤x≤1, 0≤y≤1 and 0≤x+y≤1. The light emitted by the semiconductor light-emitting device 10 (20, 30 and 40) is determined by the composition of the active layer 103b (203b, 303 b and 403b). For example, when the material of the active layer includes AlGaInP-based semiconductor, the semiconductor light-emitting device emits an infrared light with a peak wavelength of 700 to 1700 nm, a red light with a peak wavelength of 610 nm to 700 nm, or a yellow light with peak wavelength from 530 nm to 570 nm. When the material of the active layer includes InGaN, the semiconductor light-emitting device emits a blue light or a deep blue light with a peak wavelength of 400 nm to 490 nm, or a green light with a peak wavelength of 490 nm to 550 nm. When the material of the active layer includes AlGaN, the semiconductor light-emitting device emits ultraviolet light with a peak wavelength of 250 nm to 400 nm.

In the above-mentioned embodiments, the material of the transparent electrode 106 (206, 306 and 406) can be selected according to the materials of the second semiconductor contact layers 104 (204, 304 and 404) so that the transparent electrodes 106 (206, 306 and 406) and the second semiconductor contact layer 104 (204, 304 and 404) forms a good electrical contact, such as ohmic contact. In one embodiment, the transparent electrode 106 (206, 306 and 406) includes conductive metal oxide, such as indium tin oxide. The first electrode pads 108 (208, 308 and 408) and the second electrode pads 109 (209, 309 and 409) include single metal layer or multi-layered metal structure. The material of the first electrode pads 108 (208, 308 and 408) and the second electrode pads 109 (209, 309 and 409) can be Ni, Ti, Pt, Pd, Ag, Au, Al and Cu. In one embodiment, the areas of the first electrode pad 108 (208, 308 and 408) and the second electrode pad 109 (209, 309 and 409) projected on the substrate 100 (200, 300 and 400) are substantially equal. The first electrode pads 108 (208, 308 and 408) and the second electrode pads 109 (209, 309 and 409) can be soldering pads to connect to an external circuit.

In the above-mentioned embodiments, the protective layers 107 (207, 307 and 407) and the insulating layers 117 (217, 317 and 417) include dielectric materials, such as tantalum oxide, aluminum oxide, silicon oxide, titanium oxide, silicon nitride, niobium oxide or spin-on glass (SOG). In one embodiment, the protective layer 107 (207, 307 and 407) and/or the insulating layer 117 (217, 317 and 417) include distributed Bragg reflector (DBR) structure, wherein the DBR structure includes a plurality of first dielectric layers and a plurality of second dielectric layers alternately laminated. The first dielectric layer and the second dielectric layer have different refractive indexes. When the light emitted by the semiconductor light-emitting device 10 (20, 30 and 40) passes through the substrate 100 (200, 300 and 400) and extracted from the rear surface of the substrate, the protective layer 107 (207, 307 and 407) and/or the insulating layer 117 (217, 317 and 417) with the DBR structure benefits the light reflection toward the substrate 100 (200, 300 and 400), so as to increase the efficiency of the semiconductor light-emitting device 10 (20, 30 and 40).

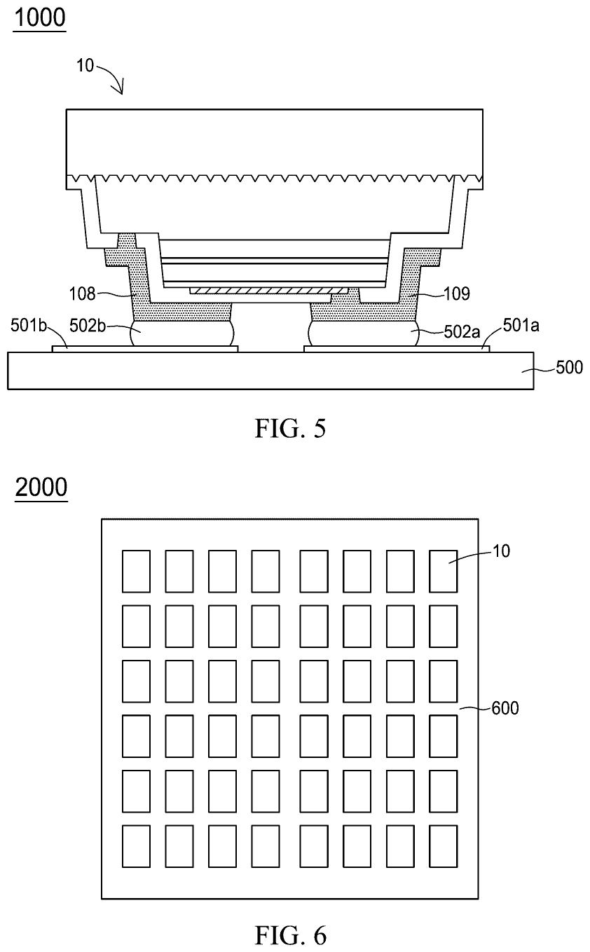

FIG. 5 shows a semiconductor light-emitting assembly having the semiconductor light-emitting device in accordance with any of embodiment of the present application flip-bonded on a carrier 500. The semiconductor light-emitting assembly 1000 includes a semiconductor light-emitting device selected from any of the embodiments described above. For example, the semiconductor light-emitting assembly 1000 includes the semiconductor light-emitting device 10 of the first embodiment having the first electrode pad 108 and the second electrode pad 109, the carrier 500 having a third electrode pad 501a and a fourth electrode pad 501b, a first bonding metal 502a bonding the first electrode pad 108 to the third electrode pad 501a, and a second bonding metal 502b bonding the second electrode pad 109 to the fourth electrode pad 501b. In one embodiment, the carrier 500 is, for example, a package submount or a printed circuit board (PCB). The third electrode pad 501a and the fourth electrode pad 501b include single metal layer or multi-layered metal structure and include metal material, such as Ni, Ti, Pt, Pd, Ag, Au, Al, Cu, an alloy or a composition composed of any of the above materials. The first bonding metal 502a and the second bonding metal 502b include, for example, solder.

FIG. 6 shows a top view of another semiconductor light-emitting assembly 2000 having a carrier and a plurality of the semiconductor light-emitting devices in accordance with any embodiment of the present application bonded on the carrier. The semiconductor light-emitting assembly 2000 includes the carrier 600 and the plurality of semiconductor light-emitting devices selected from any of the embodiments described above such as the semiconductor light-emitting device 10 of the first embodiment. The plurality of semiconductor light-emitting devices 10 is bonded to the carrier board 600 by flip-chip bonding as shown in FIG. 5 or wire bonding. In one embodiment, the semiconductor light-emitting assembly 2000 includes the semiconductor light-emitting elements 10 with different wavelengths arranged in a two-dimensional array on the carrier 600. The plurality of semiconductor light-emitting devices 10 of the semiconductor light-emitting assembly 2000 are arranged to form a plurality of RGB pixels of a display devices. Each pixel includes a red semiconductor light-emitting device, a green semiconductor light-emitting device and a blue semiconductor light-emitting device. The dominant wavelength or peak wavelength of the above-mentioned semiconductor light-emitting devices of each color are, for example, 600 nm to 660 nm, 515 nm to 575 nm, and 430 nm to 490 nm, respectively. In another embodiment, the semiconductor light-emitting assembly 2000 emits white light as a backlight module of a display device.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A semiconductor light-emitting device, comprising:
a semiconductor stack, comprising:
a first semiconductor contact layer, comprising an upper surface;
an active layer, formed on the upper surface of the first semiconductor contact layer;
a second semiconductor contact layer, formed on the active layer; and
a recessed region, formed in the semiconductor stack and comprising a part of the upper surface of the first semiconductor contact layer;
a transparent electrode on the second semiconductor contact layer;
a protective layer on semiconductor stack, comprising a first opening and a second opening;
a first electrode pad, filling in the first opening and electrically connect with the first semiconductor contact layer; and
a second electrode pad, filling in the second opening and electrically connect the transparent electrode;
wherein: the semiconductor light-emitting device receives an operating current while being operated, and a ratio of the operating current to the area of the transparent electrode ranges from 10 mA/mm² to 1000 mA/mm²; and
wherein in a top view, the active layer surrounds the recessed region;
the semiconductor stack comprises a contour with a first edge and a second edge opposite to the first edge, a third edge and a fourth edge are opposite to the third edge, and the fourth edge is adjacent to the recessed region;
the transparent electrode layer comprises s a fifth edge and a sixth edge opposite to the fifth edge, a seventh edge and an eighth edge opposite the seventh edge, and the eighth edge is adjacent to the recessed region;
the fifth edge is closer to the first edge than the sixth edge; and
a minimum distance between the fifth edge and the first edge is smaller than the eighth edge and the fourth edge.

2. The semiconductor light-emitting device according to claim 1, wherein the fifth edge is between 5 μm and 50 μm.

3. The semiconductor light-emitting device according to claim 1, wherein the operating current is between 0.01 mA and 2 mA.

4. The semiconductor light-emitting device according to claim 1, wherein the ratio of the operating current to the area of the transparent electrode ranges from 250 mA/mm² to 1000 mA/mm².

5. The semiconductor light-emitting device according to claim 1, wherein the protective layer comprises a plurality of first dielectric layers and a plurality of second dielectric layers alternately laminated.

6. The semiconductor light-emitting device according to claim 1, wherein a ratio of an area of one of the first electrode pad and the second electrode pad to an area of the transparent electrode is 0.5 to 5.

7. The semiconductor light-emitting device according to claim 1, wherein an area of the first electrode pad or an area of the second electrode pad is greater than or equal to an area of the transparent electrode.

8. The semiconductor light-emitting device according to claim 1, wherein in the top view, a minimum distance between the eighth edge and the recessed region is smaller than a minimum distance between the first edge and the recessed region.

9. The semiconductor light-emitting device according to claim 1, wherein in the top view, the second semiconductor contact layer comprises a top surface; and
wherein the top surface comprises a portion disposed between the first edge and the recessed region and the portion is not covered by the transparent electrode.

10. The semiconductor light-emitting device according to claim 1, wherein in the top view, the second semiconductor contact layer comprises a top surface; and
wherein the top surface comprises a portion corresponding to the second opening, and a part of the portion is not covered by the transparent electrode.

11. The semiconductor light-emitting device according to claim 1, wherein the first electrode pad directly contacts the upper surface of the first semiconductor contact layer in the first opening.

12. The semiconductor light-emitting device according to claim 1, wherein in the top view, the transparent electrode comprises a first aspect ratio and the contour of the semiconductor stack comprises a second aspect ratio;
wherein the second aspect ratio is greater than the first aspect ratio.

13. A semiconductor light-emitting assembly, comprising:
a carrier;
a third electrode pad and a fourth electrode pad on the carrier; and
the semiconductor light-emitting device according to claim 1 formed on the carrier;
wherein the third electrode pad and the fourth electrode pad connect to the first electrode pad and the second electrode pad of the semiconductor light-emitting device, respectively.

14. A semiconductor light-emitting assembly, comprising:
a carrier;
a plurality of electrode pads on the carrier; and
a plurality of the semiconductor light-emitting device according to claim 1 formed on the carrier;
wherein the plurality of electrode pads connects to the first electrode pads and the second electrode pads of the plurality of the semiconductor light-emitting device, respectively.
